(19) United States
(12) Patent Application Publication
(10) Pub. No.: US 2025/0207862 A1
(43) Pub. Date: Jun. 26, 2025

(54) APPARATUS FOR THERMAL CONTROL OF A WAFER

(71) Applicant: ASM IP Holdings B.V., Almere (NL)

(72) Inventors: Masaei Suwada, Nagaoka-shi (JP); Taira Okabe, Kawasaki-shi (JP); Masashi Nakano, Tokyo (JP); Samer Banna, Phoenix, AZ (US)

(21) Appl. No.: 18/982,970

(22) Filed: Dec. 16, 2024

Related U.S. Application Data
(60) Provisional application No. 63/613,871, filed on Dec. 22, 2023.

(51) Int. Cl. F28D 1/06

(52) U.S. Cl. CPC F28D 1/06

(57) ABSTRACT

An apparatus with a wafer temperature control capabilities is presented. The apparatus comprising: a plate configured to control a temperature of the wafer placed on it, a cool tank and a hot tank to store a cool and hot fluid respectively, a cooling & heating device to cool & heat the fluid in the cool tank and the hot tank respectively, an exit switch valve configured to control a direction of the fluid coming out of the plate, an input switch valve configured to control a direction of the fluid going into the plate, a first fluid line, a second fluid line, a third fluid line, and a fourth fluid line; a pump configured to pump the fluid in the input path into the plate; and a controller configured to control an opening state of the exit switch valve and the input switch valve.

### CROSS-REFERENCE TO RELATED APPLICATION(S)

This application claims the benefit of U.S. Provisional Application 63/613,871 filed on Dec. 22, 2023, the entire contents of which are incorporated herein by reference.

### FIELD OF INVENTION

The present disclosure relates to a substrate support apparatus, more particularly to an apparatus which has the capabilities to control the temperature of a substrate placed on it.

### BACKGROUND OF THE DISCLOSURE

In Semiconductor manufacturing and/or processing, the substrates need cooling and heating in various steps.

However, the plate for cooling substrates has a high heat capacity and heat mode change, i.e., from heating to cooling or from cooling to heating, takes much time. In addition, the coolant may vaporize easily when the mode changes from cooling to heating.

Therefore, the present disclosure presents a rather simple and easy system and method for heating and/or cooling wafers in a same space.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, an apparatus for thermal control of a wafer, the apparatus comprising: a plate configured to control a temperature of the wafer placed on it; a cool tank configured to store a fluid; a cooling device configured to cool the fluid in the cool tank to a temperature below a first threshold; a hot tank configured to store the fluid; a heating device configured to heat the fluid in the hot tank to another temperature above a second threshold; an exit switch valve configured to control a direction of the fluid coming out of the plate; an input switch valve configured to control a direction of the fluid going into the plate; a first fluid line disposed between the exit switch valve and the hot tank, and configured to fluidly connect the exit switch valve and the hot tank; a second fluid line disposed between the exit switch valve and the cool tank, and configured to fluidly connect the exit switch valve and the cool tank; a third fluid line disposed between the hot tank and the input switch valve, and configured to fluidly connect the hot tank and the input switch valve; a fourth fluid line disposed between the cool tank and the input switch valve, and configured to fluidly connect the cool tank and the input switch valve; a pump disposed on the input path. and configured to pump the fluid in the input path into the plate; and a controller electrically coupled to the exit switch valve and the input switch valve, configured to control an opening state of the exit switch valve and the input switch valve.

In at least one aspect, the plate further comprising a first portion and a second portion, wherein a fluid path is engraved on the first portion, and the engraved fluid path is a long continuous route without overlapping, and wherein a first end of the fluid path and a second end of the fluid path are exposed to an outside of the plate, and the first portion and the second portion are configured to seal the fluid path.

In at least one aspect, the apparatus further comprising an input path disposed between the input switch valve and the first end of the fluid path, configured to fluidly connect the input switch valve and the first end of the fluid path; and an output path disposed between the second end of the fluid path and the exit switch valve, and configured to fluidly connect the second end of the fluid path and the exit switch valve.

In at least one aspect, the apparatus further comprising a first bonding disposed at the first end of the fluid path and configured to seal a contact area of the first end of the fluid path and the input path; and a second bonding disposed at the second end of the fluid pipe and configured to seal a contact area of the second of the fluid path and the output path.

In at least one aspect, the plate further comprising a first portion and a second portion and a pipe, wherein the fluid pipe is a long continuous route covering the plate, and wherein a first end of the fluid pipe and a second end of the fluid pipe are exposed to an outside of the plate, and the fluid pipe is disposed between the first portion and the second portion.

In at least one aspect, the apparatus further comprising: an input path disposed between the input switch valve and the first end of the fluid pipe and configured to fluidly connect the input switch valve and the first end of the fluid pipe; and an output path disposed between the second end of the fluid pipe and the exit switch valve and configured to fluidly connect the second end of the fluid pipe and the exit switch valve.

In at least one aspect, the apparatus further comprising: a first bonding disposed at the first end of the fluid pipe and configured to seal a contact area of the first end of the fluid pipe and the input path; and a second bonding disposed at the second end of the fluid pipe and configured to seal a contact area of the second of the fluid pipe and the output path.

In at least one aspect, the apparatus further comprising a filler configured to fill in a space between the first portion, the second portion and outside of the fluid pipe.

In accordance with one embodiment there may be provided, an apparatus for thermal control of a wafer, the apparatus comprising: a plate configured to control a temperature of the wafer placed on it; a cool tank configured to store a fluid; a cooling device configured to cool the fluid in the cool tank to a temperature below a first threshold; a hot tank configured to store the fluid; a heating device configured to heat the fluid in the hot tank to a temperature above a second threshold; an exit switch valve configured to control a direction of the fluid coming out of the plate; an input switch valve configured to control a direction of the fluid going into the plate; a first fluid line disposed between the exit switch valve and the hot tank, and configured to fluidly connect the exit switch valve and the hot tank; a second fluid line disposed between the exit switch valve and the cool tank, and configured to fluidly connect the exit switch valve and the cool tank; a third fluid line disposed between the hot tank and the input switch valve, and configured to fluidly connect the hot tank and the input switch valve; a fourth fluid line disposed between the cool tank and the input switch valve, and configured to fluidly connect the cool tank and the input switch valve; a first pump configured to pump the fluid in the hot tank into the plate; a second pump configured to pump the fluid in the cool tank into the plate; and a controller electrically coupled to the exit switch valve and the input switch valve, configured to control an opening state of the exit switch valve and the input switch valve.

In at least one aspect, the plate further comprising a first portion and a second portion, wherein a fluid path is engraved on the first portion, and the engraved fluid path is a long continuous route without overlapping, and wherein a first end of the fluid path and a second end of the fluid path are exposed to an outside of the plate, and the first portion and the second portion are configured to seal the fluid path.

In at least one aspect, the apparatus further comprising an input path disposed between the input switch valve and the first end of the fluid path and configured to fluidly connect the input switch valve and the first end of the fluid path; an output path disposed between the second end of the fluid path and the exit switch valve and configured to fluidly connect the second end of the fluid path and the exit switch valve.

In at least one aspect, the apparatus further comprising a first bonding disposed at the first end of the fluid path and configured to seal a contact area of the first end of the fluid path and the input path; and a second bonding disposed at the second end of the fluid pipe and configured to seal a contact area of the second of the fluid path and the output path.

In at least one aspect, the plate further comprising a first portion and a second portion and a fluid pipe, wherein the fluid pipe is a long continuous route covering the plate, and wherein a first end of the fluid pipe and a second end of the fluid pipe are exposed to an outside of the plate, and the fluid pipe is disposed between the first portion and the second portion.

In at least one aspect, the apparatus further comprising: an input path disposed between the input switch valve and the first end of the fluid pipe and configured to fluidly connect the input switch valve and the first end of the fluid pipe; and an output path disposed between the second end of the fluid pipe and the exit switch valve and configured to fluidly connect the second end of the fluid pipe and the exit switch valve.

In at least one aspect, the apparatus further comprising: a first bonding disposed at the first end of the fluid pipe and configured to seal a contact area of the first end of the fluid pipe and the input path; and a second bonding disposed at the second end of the fluid pipe and configured to seal a contact area of the second of the fluid pipe and the output path.

In at least one aspect, the apparatus further comprising: a filler configured to fill in a space between the first portion, the second portion and outside of the fluid pipe.

In at least one aspect, the controller further electrically coupled to the first pump and the second pump, further configured to control an operating state of the first pump and the second pump.

In at least one aspect, the controller further configured: to control the input switch valve to open the third fluid line and the exit switch valve to open the first fluid line for a heated fluid circulation, and to control the input switch valve to open the fourth fluid line and the exit switch valve to open the second fluid line for a cooled fluid circulation.

In at least one aspect, a boiling point of the fluid is above a third threshold temperature.

In at least one aspect, the first portion and the second portion are black-anodized, and a thickness of the plate is equal to or less than 15 mm.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates one schematic overview of the overall apparatus according to an embodiment of the present disclosure.

FIG. 2 illustrates another schematic overview of the overall apparatus according to another embodiment of the present disclosure.

FIG. 3 illustrates a different perspective view of the plate according to an embodiment of the present disclosure.

FIG. 4 illustrates a different setup of the control valves according to another embodiment of the present disclosure.

FIG. 5 illustrates a different perspective view of the plate according to another embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous;

rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

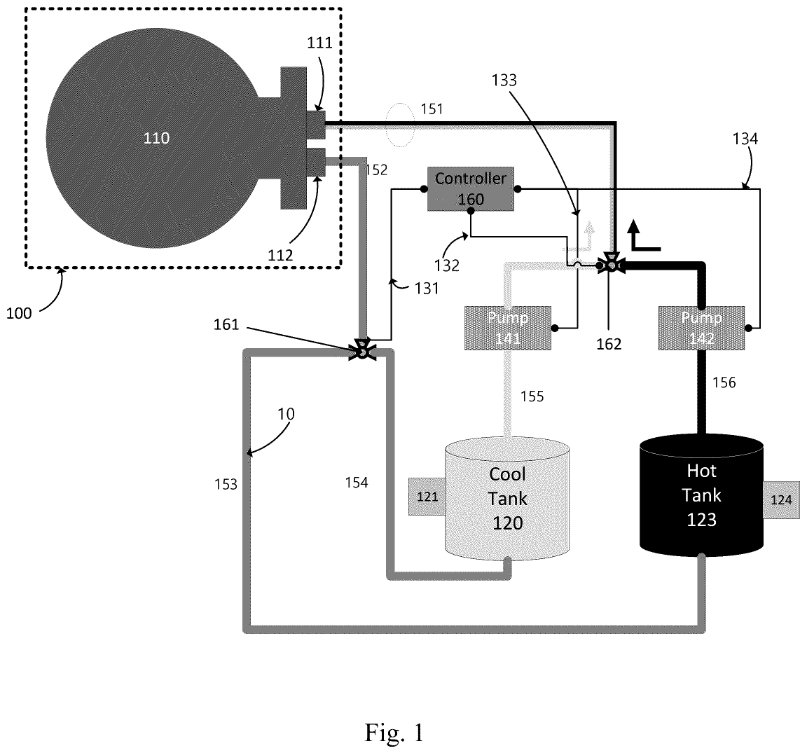

FIG. 1 illustrates one schematic overview of the overall apparatus according to an embodiment of the present disclosure.

Usually, a substrate cooling/heating would occur inside of a chamber 100. In the chamber 100, a plate 110 for cooling/heating (thermal control) a substrate placed on it is shown.

For cooling or heating a substrate on the plate 110, a fluid 10 may be used. The apparatus also comprises a cool tank 120 and a hot tank 123 for storing the fluid and a cooling device 121 and a heating device 124 for cooling and heating the fluid in respective tanks 120, 123. The apparatus also comprises an input switch valve 162 and an exit switch valve 161 for switching between the tanks (120, 123) for choosing which operation (cooling or heating) to be applied to the substrate placed on the plate. The apparatus may also comprise an input path 151 and output path 152 for the fluid going into the plate 110 or out of the plate 110 respectively.

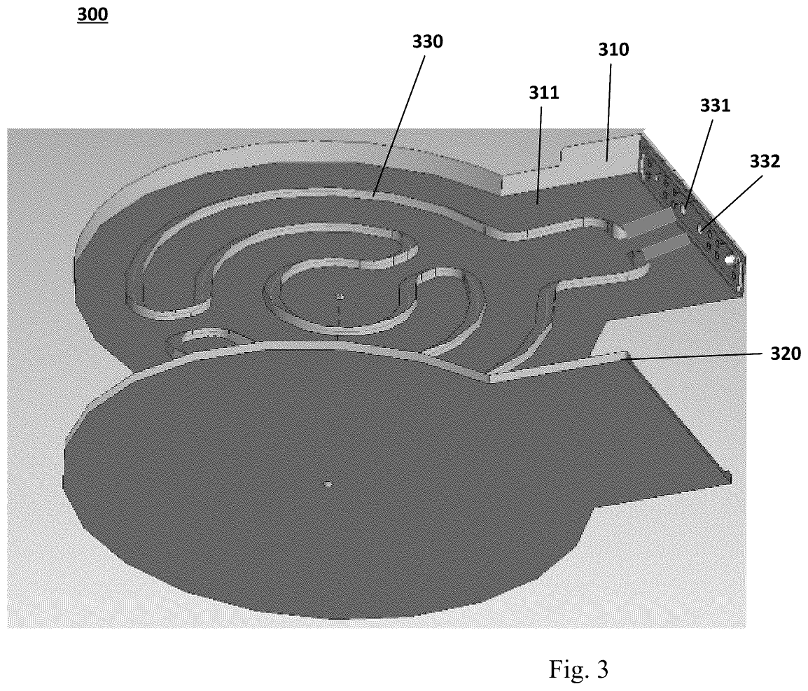

The inside of the plate may be illustrated in FIG. 3. As shown, the plate 300 may comprise a first portion 310 and a second portion 320. The first portion 310 would be a little thicker than the second portion 320 and a fluid path 330 may be engraved on the first portion 310 (the thicker one). The fluid path 330 would be a long, continuous route covering all the first portion 310 of the plate 300 and the fluid path 330 does not overlap. The first portion 310 outside of the fluid path 330, i.e., an area 311, would be a heat conducting material like Al and/or any other material with high conductivity. The two end of the fluid path 331, 332 may be exposed to the outside of the plate and may be used as a fluid entry point and exit point. When the first portion 310 and the second portion 320 may be attached, the fluid path 330 may be sealed completely such that no fluid may be leaked from it.

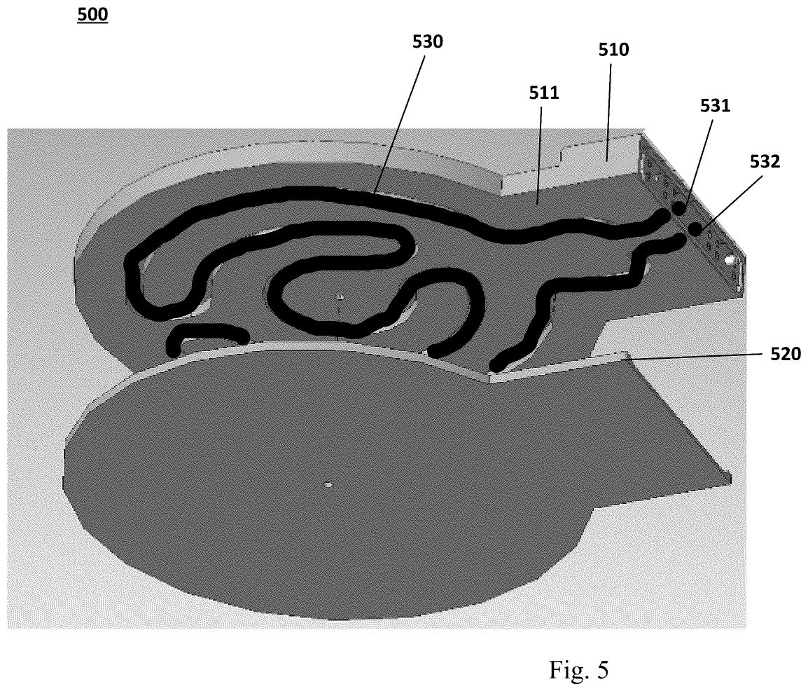

In FIG. 5, in another embodiment, the plate 500 may comprise a first portion 510 and a second portion 520 and a fluid pipe 530. The fluid pipe 530 is a separate curved pipe and it has the same coverage as that of the engraved fluid path 330. Outside of the fluid pipe 530 between the first and second portion 510, 520 may be filled with a filler 511, and this filler 511 may comprise a high conducting material like Al. Any other material except Al could be used if it (or the mixture of materials) has high heat conductivity.

The cooling device 121 may cool down the temperature of the fluid inside of the cool tank 120. A low threshold temperature may be set for the device 121 to maintain the temperature of the fluid in the cool tank 120 below the low threshold.

The heating device 124 may heat up the temperature of the fluid inside of the hot tank 123. A high threshold temperature may be set for the heating device 124 to maintain the temperature of the hot tank 123 above the high threshold. Usually, the low threshold may be equal to or lower than 20 (degrees in Celsius) and the high threshold may be equal to or higher than 270 (degrees in Celsius).

When heating up a substrate on the plate 110, the fluid from the hot tank 123 got pumped by a second pump 142 into the plate 110 via a third fluid line 156. The input switch valve 162 may be open for the third fluid line 156 (This means the fourth fluid line 155 is shut) and the hot fluid heated more than the high threshold goes through the input path 151 into a first end of the fluid path 331 (or fluid pipe 531). The hot fluid runs along the fluid path 330 (or the fluid pipe 530) and heats up a substrate placed on the plate 110 and a temperature of the fluid may drop. The cooled fluid may exit the plate 110 from a second end of the fluid path 332 (or fluid pipe 532). The fluid 10 then goes through the exit path 152 to the exit switch valve 161. The exit switch valve 161 may be open the first fluid line 153 (while the second fluid line 154 is shut) for the cooled fluid to return to the hot tank 123 for re-heating.

When cooling down a substrate on the plate 110, the fluid 10 from the cool tank 120 got pumped by a first pump 141 into the plate 110 via a fourth fluid line 155. The input switch valve 162 may be open for the fourth fluid line 155 (This means the third fluid line 156 is shut) and the cool fluid cooled below the low threshold goes through the input path 151 into a first end of the fluid path 331 (or fluid pipe 531). The cool fluid runs along the fluid path 330 (or fluid pipe 530) and cools down a substrate placed on the plate 110 and a temperature of the fluid 10 may rise. The somewhat heated fluid may exit the plate 110 from a second end of the fluid path 332 (or fluid pipe 532). The fluid 10 then goes through the exit path 152 to the exit switch valve 161. The exit switch valve 161 may be open the second fluid line 154 (while the first fluid line 153 is shut) for the heated fluid to return to the cool tank 120 for re-cooling.

The opening/closing of the input switch valve 162 and the exit switch valve 161 may be controlled by a controller 160. The controller 160 may be electrically connected to the exit switch valve 161 and the input switch valve 162 with wire or wirelessly (131, 132) respectively.

The controller 160 may also be configured to control the input switch valve 162 and the exit switch valve 161 such that when the third fluid line 156 may open (this means the fourth fluid line 155 is closed), the first fluid line 153 may open (this means the second fluid line 154 is closed) at the same time. The controller 160 also may be configured to control the input switch valve 162 and the exit switch valve 161 such that when the fourth fluid line 155 may open (this means the third fluid line 156 is closed), and the second fluid line 154 may open (this means the first fluid line 153 is closed) at the same time.

The controller 160 may also be connected to the first and second pumps 141, 142 for controlling the operations 133, 134, respectively. When heating a substrate, the cool fluid in the cool tank 120 may not be needed, therefore the controller 160 may control the first pump 141 to stop while the second pump 142 to operate. In cooling a substrate, the hot fluid in the hot tank 123 may not be needed, therefore the controller 160 may control the second pump 142 to stop while the first pump 141 to operate.

In some applications, additional fluid sealing may be needed. As shown in FIGS. 1, 3 & 5, the first and second end of the fluid path 331, 332 (or fluid pipe 531, 532) may be connected to the input path 151 and output path 152 and a first bonding 111 may be sealing the contact area of the input path 151 and the first end of the fluid path 331 (or fluid pipe 531) and a second bonding 112 may be sealing the contact area of the output path 152 and the second end of the fluid path 332 (or fluid pipe 532).

In some applications, the input path 151 and/or output path 152 may not be needed.

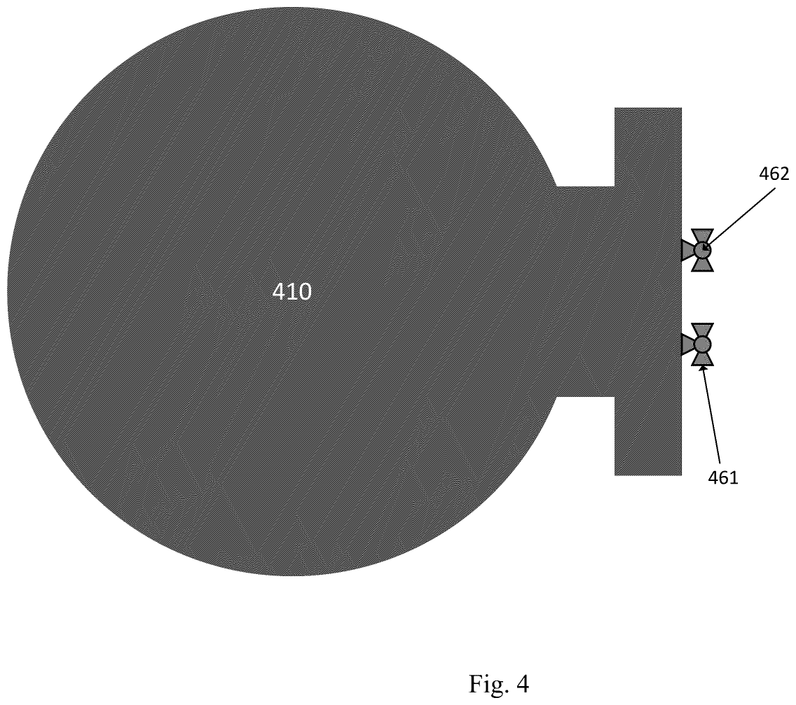

In FIG. 4, the plate 410 may be setup to be connected directly to an input switch valve 461 and an output switch valve 462. In this case, the first bonding 111 and second bonding 112 may not be needed.

In another embodiment, there may be 1 (one) pump instead of 2 (two) pumps.

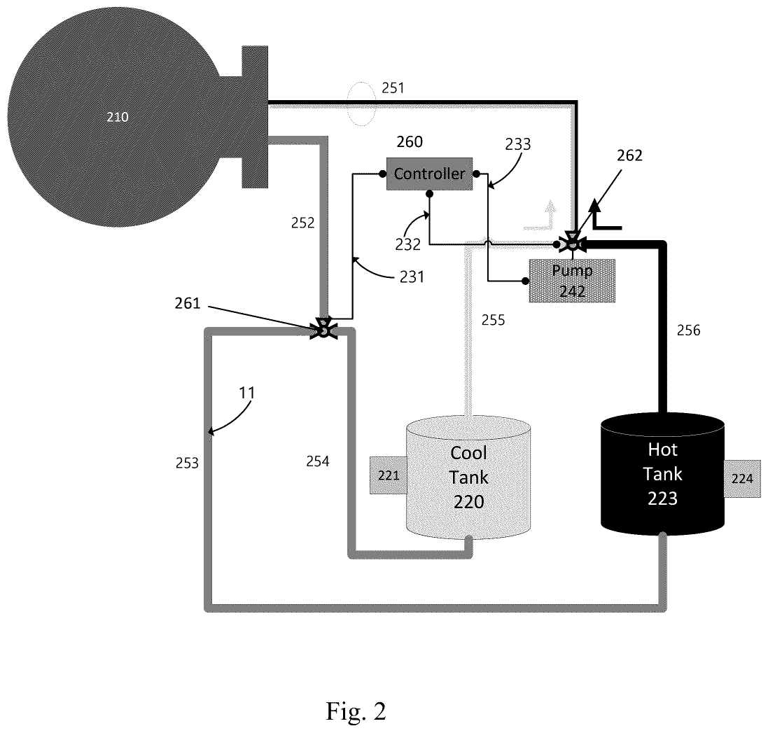

In FIG. 2, a plate 210 for cooling/heating (thermal control) a substrate placed on it is shown.

For cooling or heating a substrate on the plate 210, a fluid 11 may be used. The apparatus also comprises a cool tank 220 and a hot tank 223 for storing the fluid 11 and a cooling device 221 and a heating device 224 for cooling and heating the fluid in respective tanks 220, 223. The apparatus also comprises an input switch valve 262 and an exit switch valve 261 for switching between the tanks (220, 223) for choosing which operation (cooling or heating) to be applied to the substrate placed on the plate 210. The apparatus may also comprise an input path 251 and output path 252 for the fluid 11 going into the plate 210 or out of the plate 210 respectively.

The cooling device 221 may cool down the temperature of the fluid 11 inside of the cool tank 220. The low threshold temperature may be set for the device 221 to maintain the temperature of the fluid in the cool tank 220 below the low threshold.

The heating device 224 may heat up the temperature of the fluid 11 inside of the hot tank 223. The high threshold temperature may be set for the heating device 224 to maintain the temperature of the hot tank 223 above the high threshold.

When heating up a substrate on the plate 210, the fluid 11 from the hot tank 223 got pumped by a pump 242 into the plate 210 via a third fluid line 256. The input switch valve 262 may be open for the third fluid line 256 (This means the fourth fluid line 255 is closed) and the hot fluid heated more than the high threshold may go through the input path 251 into a first end of the fluid path 331 (or fluid pipe 531). The hot fluid runs along the fluid path 330 (or fluid pipe 530) and heats up a substrate placed on the plate 210 and a temperature of the fluid 11 may drop. The cooled fluid may exit the plate 210 from a second end of the fluid path 332 (or fluid pipe 532). The fluid 11 then goes through the exit path 252 to the exit switch valve 261. The exit switch valve 261 may be open the first fluid line 253 (while the second fluid line 254 is closed) for the cooled fluid to return to the hot tank 223 for re-heating.

When cooling down a substrate on the plate 210, the fluid 11 from the cool tank 220 got pumped by the pump 142 into the plate 210 via a fourth fluid line 255. The input switch valve 262 may be open for the fourth fluid line 255 (This means the third fluid line 256 is closed) and the cool fluid cooled below the low threshold may go through the input path 251 into a first end of the fluid path 331 (or fluid pipe 531). The cool fluid runs along the fluid path 330 (or fluid pipe 530) and cools down a substrate placed on the plate 210 and a temperature of the fluid 11 may rise. The somewhat heated fluid may exit the plate 210 from a second end of the fluid path 332 (or fluid pipe 532). The fluid 11 then goes through the exit path 252 to the exit switch valve 261. The exit switch valve 261 may be controlled to open the second fluid line 254 (while the first fluid line 253 is closed) for the heated fluid to return to the cool tank 220 for re-cooling.

The opening/closing of the input switch valve 262 and the exit switch valve 261 may be controlled by a controller 260. The controller 260 may be electrically connected to the exit switch valve 261 and the input switch valve 262 with wire or wirelessly (231, 232) respectively.

The controller 260 may also be configured to control the input switch valve 262 and the exit switch valve 261 such that when the third fluid line 256 may open (this means the fourth fluid line 255 is closed), the first fluid line 253 may open (this means the second fluid line 254 is closed) at the same time. The controller 260 also may be configured to control the input switch valve 262 and the exit switch valve 261 such that when the fourth fluid line 255 may open (this means the third fluid line 256 is closed), and the second fluid line 254 may open (this means the first fluid line 253 is closed) at the same time.

The controller 160 may also be connected to the pump 242 for controlling its operations (233) such as speed up/down, turn on/off.

The fluid (10, 11) may have a high boiling point for efficient thermal control. The boiling point may be higher than the high threshold for not being vaporized when heated. The boiling point of the fluid may be another threshold higher than a boil threshold and the boil threshold may be higher than the high threshold.

For efficient thermal control, the thickness of the plate 110, 210 may need to be thin enough. Preferably, the thickness of the plate 110, 210 may be equal to or less than 15 mm.

The plate, i.e., the first portion, the second portion and the fluid pipe too, and the filler may be anodized in black for maximum heat conductivity and may made of materials which comprise aluminum (Al), copper (Cu), and other high heat conductive materials or alloys, and a mixture of two or more of them. The plate and fluid lines may be made of materials resistant to electrolytic corrosion too.

The above-described arrangement of apparatus is merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. An apparatus for thermal control of a wafer, the apparatus comprising:
a fluid;
a plate configured to control a temperature of the wafer placed on it using the fluid;
a cool tank and a hot tank configured to store the fluid;
a cooling device configured to cool the fluid in the cool tank to a first temperature below a first threshold;
a heating device configured to heat the fluid in the hot tank to second temperature above a second threshold;
an exit switch valve configured to control a direction of the fluid coming out of the plate;
an input switch valve configured to control a direction of the fluid going into the plate;
a first fluid line disposed between the exit switch valve and the hot tank, and configured to fluidly connect the exit switch valve and the hot tank;
a second fluid line disposed between the exit switch valve and the cool tank, and configured to fluidly connect the exit switch valve and the cool tank;
a third fluid line disposed between the hot tank and the input switch valve, and configured to fluidly connect the hot tank and the input switch valve;
a fourth fluid line disposed between the cool tank and the input switch valve, and configured to fluidly connect the cool tank and the input switch valve;
a pump configured to pump the fluid into the plate; and
a controller electrically coupled to the exit switch valve and the input switch valve, configured to control an opening state of the exit switch valve and the input switch valve.

2. The apparatus according to claim 1, the plate further comprising a first portion and a second portion, wherein a fluid path is engraved on the first portion, and the fluid path is a long continuous route without overlapping, and
wherein a first end of the fluid path and a second end of the fluid path are exposed to an outside of the plate, and the first portion and the second portion are configured to seal the fluid path.

3. The apparatus according to claim 2, further comprising:
an input path disposed between the input switch valve and the first end of the fluid path, and configured to fluidly connect the input switch valve and the first end of the fluid path; and
an output path disposed between the second end of the fluid path and the exit switch valve, and configured to fluidly connect the second end of the fluid path and the exit switch valve.

4. The apparatus according to claim 3, further comprising
a first bonding disposed at the first end of the fluid path and configured to seal a contact area of the first end of the fluid path and the input path; and
a second bonding disposed at the second end of the fluid path and configured to seal a contact area of the second end of the fluid path and the output path.

5. The apparatus according to claim 1, the plate further comprising a first portion and a second portion and a fluid pipe, wherein the fluid pipe is a long continuous route covering the plate, and
wherein a first end of the fluid pipe and a second end of the fluid pipe are exposed to an outside of the plate, and the fluid pipe is disposed between the first portion and the second portion.

6. The apparatus according to claim 5, further comprising:
an input path disposed between the input switch valve and the first end of the fluid pipe, and configured to fluidly connect the input switch valve and the first end of the fluid pipe; and
an output path disposed between the second end of the fluid pipe and the exit switch valve, and configured to fluidly connect the second end of the fluid pipe and the exit switch valve.

7. The apparatus according to claim 6, further comprising:
a first bonding disposed at the first end of the fluid pipe and configured to seal a contact area of the first end of the fluid pipe and the input path; and
a second bonding disposed at the second end of the fluid pipe and configured to seal a contact area of the second end of the fluid pipe and the output path.

8. The apparatus according to claim 5, further comprising:
a filler configured to fill in a space between the first portion, the second portion and the fluid pipe.

9. An apparatus for thermal control of a wafer, the apparatus comprising:
a fluid;
a plate configured to control a temperature of the wafer placed on it using the fluid;
a cool tank and a hot tank configured to store the fluid;
a cooling device configured to cool the fluid in the cool tank to a temperature below a first threshold;
a heating device configured to heat the fluid in the hot tank to a temperature above a second threshold;
an exit switch valve configured to control a direction of the fluid coming out of the plate;
an input switch valve configured to control a direction of the fluid going into the plate;
a first fluid line disposed between the exit switch valve and the hot tank, and configured to fluidly connect the exit switch valve and the hot tank;
a second fluid line disposed between the exit switch valve and the cool tank, and configured to fluidly connect the exit switch valve and the cool tank;
a third fluid line disposed between the hot tank and the input switch valve, and configured to fluidly connect the hot tank and the input switch valve;
a fourth fluid line disposed between the cool tank and the input switch valve, and configured to fluidly connect the cool tank and the input switch valve;
a first pump configured to pump the fluid in the hot tank into the plate;
a second pump configured to pump the fluid in the cool tank into the plate; and
a controller electrically coupled to the exit switch valve and the input switch valve, configured to control an opening state of the exit switch valve and the input switch valve.

10. The apparatus according to claim 9, the plate further comprising a first portion and a second portion, wherein a fluid path is engraved on the first portion, and the fluid path is a long continuous route without overlapping, and
wherein a first end of the fluid path and a second end of the fluid path are exposed to an outside of the plate, and the first portion and the second portion are configured to seal the fluid path.

11. The apparatus according to claim 10, further comprising:
an input path disposed between the input switch valve and the first end of the fluid path, and configured to fluidly connect the input switch valve and the first end of the fluid path; and
an output path disposed between the second end of the fluid path and the exit switch valve, and configured to fluidly connect the second end of the fluid path and the exit switch valve.

12. The apparatus according to claim 11, further comprising
a first bonding disposed at the first end of the fluid path and configured to seal a contact area of the first end of the fluid path and the input path; and
a second bonding disposed at the second end of the fluid path and configured to seal a contact area of the second end of the fluid path and the output path.

13. The apparatus according to claim 9, the plate further comprising a first portion and a second portion and a fluid pipe, wherein the fluid pipe is a long continuous route covering the plate, and
wherein a first end of the fluid pipe and a second end of the fluid pipe are exposed to an outside of the plate, and the fluid pipe is disposed between the first portion and the second portion.

14. The apparatus according to claim 13, further comprising:
an input path disposed between the input switch valve and the first end of the fluid pipe, and configured to fluidly connect the input switch valve and the first end of the fluid pipe; and
an output path disposed between the second end of the fluid pipe and the exit switch valve, and configured to fluidly connect the second end of the fluid pipe and the exit switch valve.

15. The apparatus according to claim 14, further comprising:
a first bonding disposed at the first end of the fluid pipe and configured to seal a contact area of the first end of the fluid pipe and the input path; and
a second bonding disposed at the second end of the fluid pipe and configured to seal a contact area of the second end of the fluid pipe and the output path.

16. The apparatus according to claim 13, further comprising:
a filler configured to fill in a space made between the first portion, the second portion and the fluid pipe.

17. The apparatus according to claim 9, wherein the controller further electrically coupled to the first pump and the second pump, further configured to control an operating state of the first pump and the second pump, and wherein the controller further configured:
to control the input switch valve to open the third fluid line and the exit switch valve to open the first fluid line for a heated fluid circulation, and
to control the input switch valve to open the fourth fluid line and the exit switch valve to open the second fluid line for a cooled fluid circulation.

18. The apparatus according to claim 1, wherein the controller further configured:
to control the input switch valve to open the third fluid line and the exit switch valve to open the first fluid line for a heated fluid circulation, and
to control the input switch valve to open the fourth fluid line and the exit switch valve to open the second fluid line for a cooled fluid circulation.

19. The apparatus according to claim 2, wherein a boiling point of the fluid is above a third threshold temperature, and
the first portion and the second portion are black-anodized, and
a thickness of the plate is equal to or less than 15 mm.

20. The apparatus according to claim 10, wherein a boiling point of the fluid is above a third threshold temperature, and
wherein the first portion and the second portion are black-anodized, and
a thickness of the plate is equal to or less than 15 mm.
